(19) United States
(12) Patent Application Publication
(10) Pub. No.: US 2025/0318167 A1
(43) Pub. Date: Oct. 9, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Hung-Ju CHOU, Hsinchu (TW); Wei-Yang Lee, Taipei (TW); Yuan-Ching Peng, Hsinchu (TW)

(21) Appl. No.: 18/627,507

(22) Filed: Apr. 5, 2024

(51) Int. Cl. H01L 29/66; H01L 29/06; H01L 29/423; H01L 29/775

(52) U.S. Cl. CPC H10D 30/014; H10D 30/43; H10D 30/6735; H10D 62/121; H10D 64/017; H10D 64/021

(57) ABSTRACT

Methods for forming a semiconductor device structure are described. The method includes forming a fin structure from a substrate, depositing an insulating material around the fin structure, recessing the insulating material, and forming a sacrificial gate structure over a first portion of the fin structure. A first portion of the insulating material is covered by the sacrificial gate structure, and a second portion of the insulating material is exposed. The method further includes modifying a top surface of the exposed second portion of the insulating material, and the modified top surface has a profile different from a top surface of the first portion of the insulating material. After the modifying of the top surface, the method further includes depositing a first spacer on the sacrificial gate structure a second portion of the fin structure and recessing the second portion of the fin structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 are perspective views of various stages of manufacturing a semiconductor device structure, in accordance with some embodiments.

FIGS. 6A and 6B are cross-sectional side views of one of various stages of manufacturing the semiconductor device structure taken along lines A-A, B-B of FIG. 5, respectively, in accordance with some embodiments.

FIG. 7 is a perspective view of one of various stages of manufacturing the semiconductor device structure, in accordance with some embodiments.

FIGS. 8A and 8B are cross-sectional side views of one of various stages of manufacturing the semiconductor device structure taken along lines A-A, B-B of FIG. 5, respectively, in accordance with some embodiments.

FIG. 9 is a perspective view of one of various stages of manufacturing the semiconductor device structure, in accordance with some embodiments.

FIGS. 10A and 10B are cross-sectional side views of one of various stages of manufacturing the semiconductor device structure taken along lines B-B, C-C of FIG. 5, respectively, in accordance with some embodiments.

FIG. 11 is a perspective view of one of various stages of manufacturing the semiconductor device structure, in accordance with some embodiments.

FIGS. 12A and 12B are cross-sectional side views of one of various stages of manufacturing the semiconductor device structure taken along lines B-B, C-C of FIG. 5, respectively, in accordance with some embodiments.

FIG. 13 is a perspective view of one of various stages of manufacturing the semiconductor device structure, in accordance with some embodiments.

FIGS. 14A and 14B are cross-sectional side views of one of various stages of manufacturing the semiconductor device structure taken along lines B-B, C-C of FIG. 5, respectively, in accordance with some embodiments.

FIGS. 15-17 are cross-sectional side views of various stages of manufacturing the semiconductor device structure taken along line C-C of FIG. 5, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments to be described below relate generally to modifying the shape of an isolation region located between source/drain regions to reduce the risk of merging source/drain regions. In some embodiments, after forming the sacrificial gate structures, an additional etch process is performed to modify the shape of the isolation region not covered by the sacrificial gate structures. As a result, subsequently formed spacers on the modified isolation regions can prevent merging of adjacent source/drain regions.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

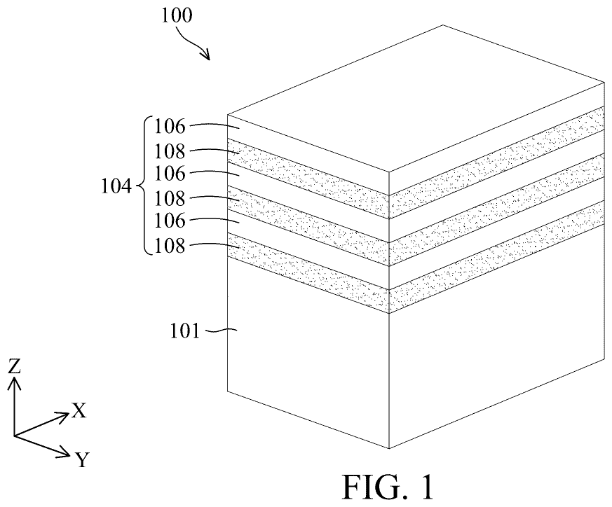

FIGS. 1-17 show exemplary processes for manufacturing a semiconductor device structure 100 according to embodiments of the present disclosure. It is understood that additional operations can be provided before, during, and after processes shown by FIGS. 1-17, and some of the operations described below can be replaced or eliminated, for additional embodiments of the method. The order of the operations/processes is not limiting and may be interchangeable.

FIGS. 1-5 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GaAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. In some embodiments, the stack of semiconductor layers 104 includes two first semiconductor layers 106. In some embodiments, the stack of semiconductor layers 104 includes three first semiconductor layers 106. In some embodiments, the stack of semiconductor layers 104 includes four first semiconductor layers 106.

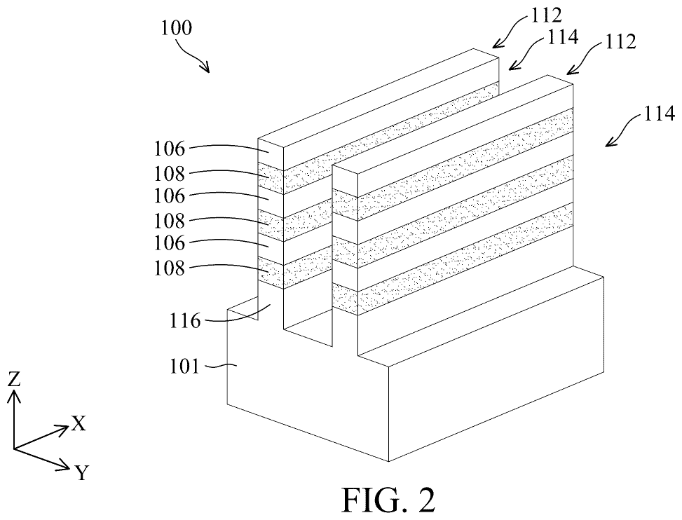

As shown in FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

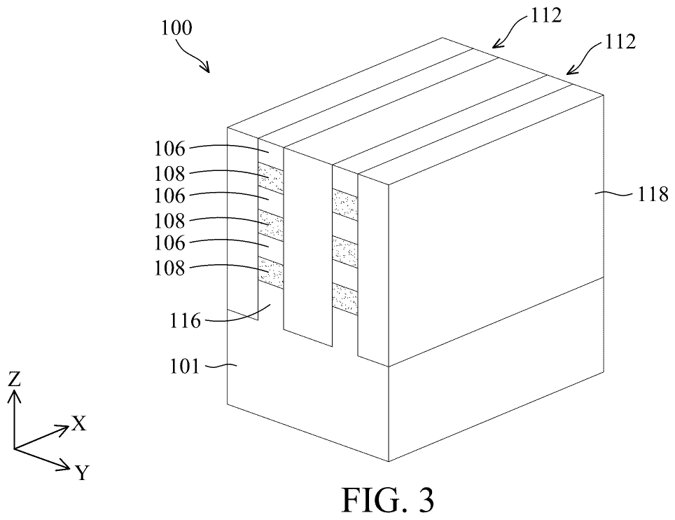

As shown in FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

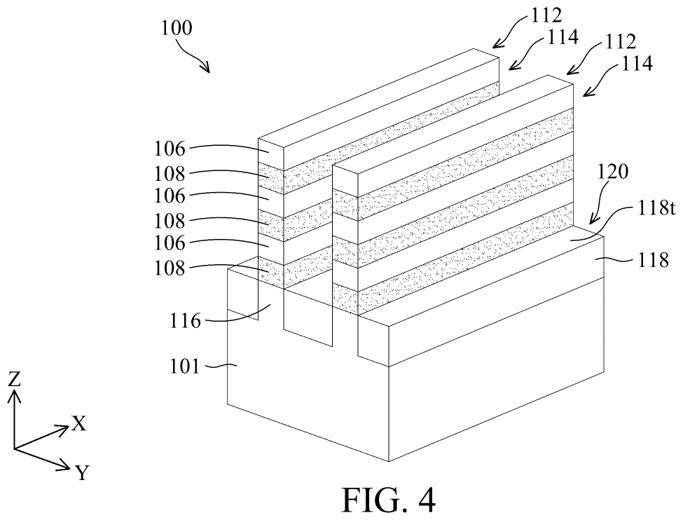

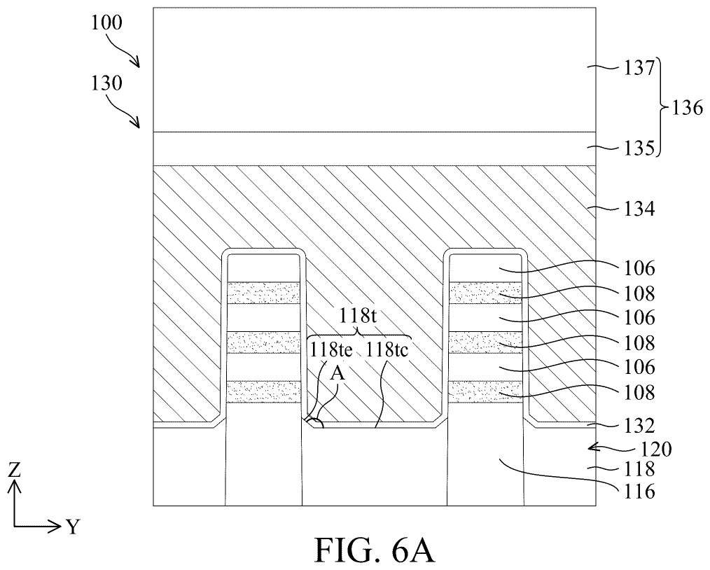

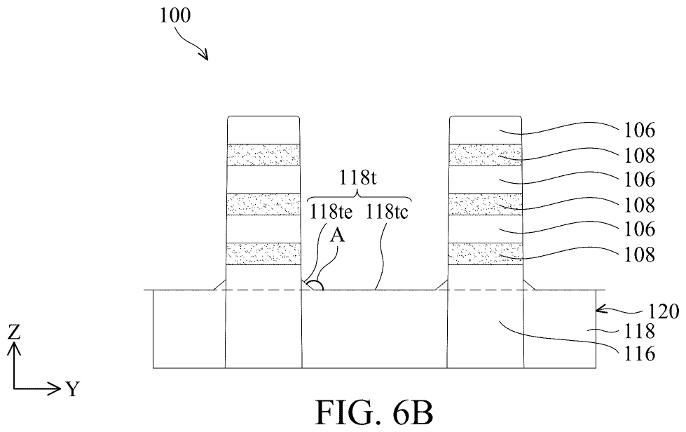

As shown in FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface 118t of the insulating material 118 may be level with or below a surface of the second semiconductor layers 108 in contact with the well portion 116 formed from the substrate 101. In some embodiments, the isolation regions 120 are the shallow trench isolation (STI) regions. In some embodiments, the top surface 118t has a “smile” profile, as shown in FIG. 6B. In some embodiments, as shown in FIG. 6B, the top surface 118t of the insulating material 118 (or the isolation region 120) includes a center top surface 118tc and an edge top surface 118te. An angle A is formed between the center top surface 118tc and the edge top surface 118te. In some embodiments, the angle A is an obtuse angle. In some embodiments, the angle A ranges from about 100 degrees to about 160 degrees. In some embodiments, a highest point of the edge top surface 118te is located at a level in the Z direction substantially higher than a highest point of the center top surface 118tc, as shown in FIG. 6B.

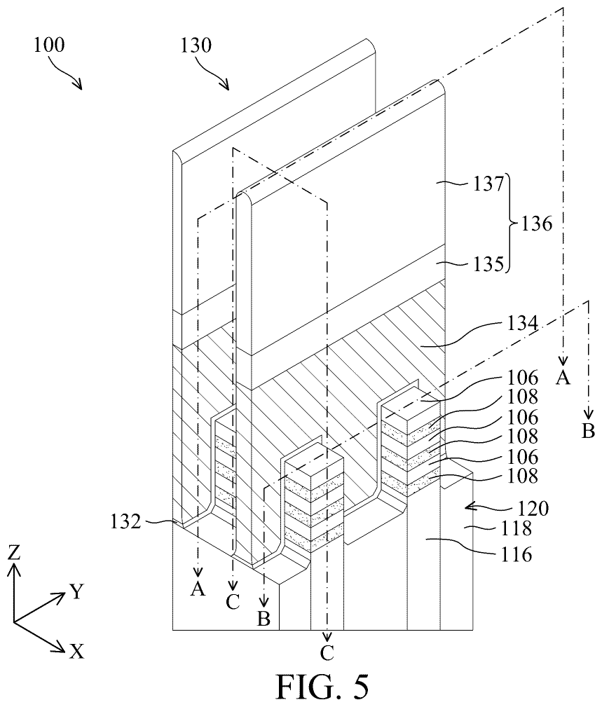

As shown in FIG. 5, one or more sacrificial gate structures 130 (two are shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. While two sacrificial gate structures 130 are shown, more or less sacrificial gate structures 130 may be arranged along the X direction in some embodiments. In some embodiments, a wet etch process is performed to form the sacrificial gate structures 130.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer 135 and a nitride layer 137. The portions of the fin structures 112 that are covered by the sacrificial gate electrode layer 134 of the sacrificial gate structure 130 serve as channel regions for the semiconductor device structure 100.

FIGS. 6A and 6B are cross-sectional side views of one of various stages of manufacturing the semiconductor device structure 100 taken along lines A-A, B-B of FIG. 5, respectively, in accordance with some embodiments. FIGS. 6A and 6B show the semiconductor device structure 100 at the same manufacturing stage as in FIG. 5. In some embodiments, the top surface 118t of the isolation region 120 covered by the sacrificial gate structures 130, as shown in FIG. 6A, has substantially the same shape as the exposed top surface 118t of the isolation region 120, as shown in FIG. 6B.

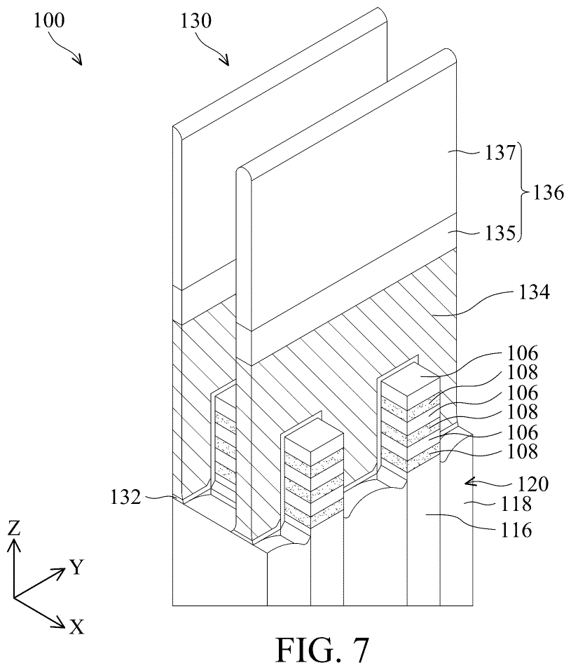

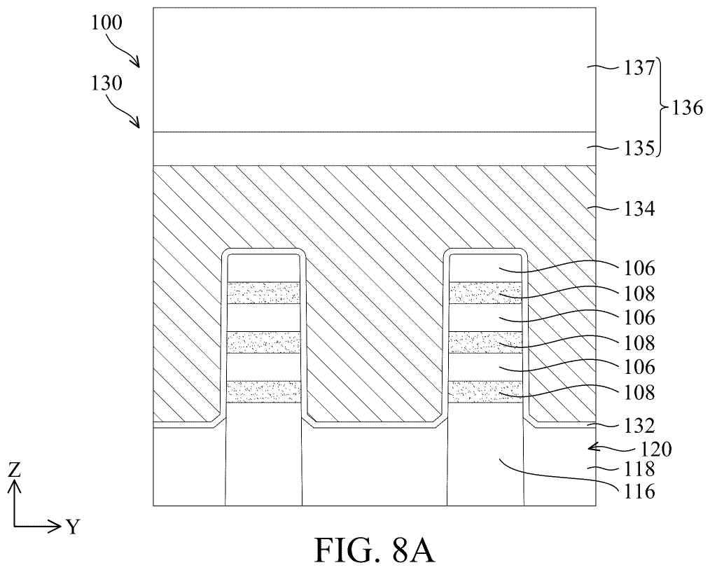

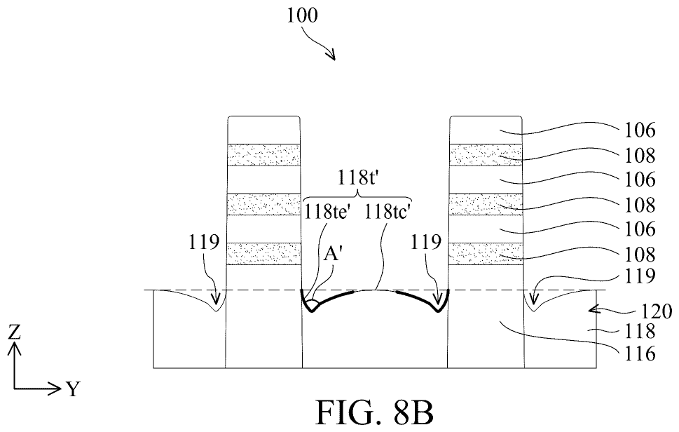

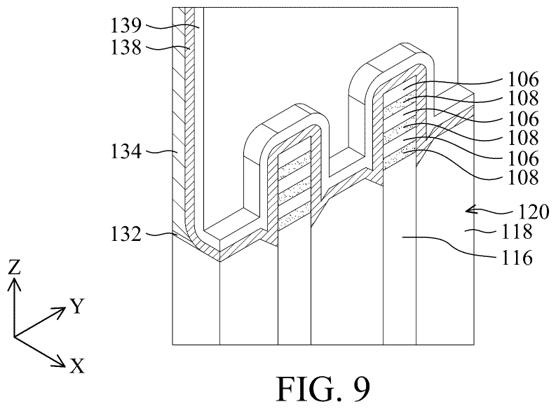

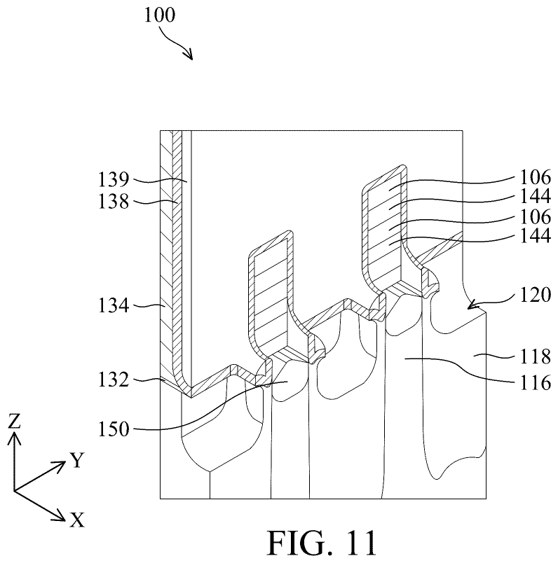

Next, as shown in FIGS. 7, 8A and 8B, an etch process is performed to modify the exposed top surface 118t of the isolation region 120. In some embodiments, the etch process is a plasma anisotropic etch process. For example, the plasma anisotropic etch process uses a main etchant, such as CF₄, to etch a portion of the exposed insulating material 118. In addition, a secondary etchant, such as Ar, along with pulsed bias voltage, may be utilized in the plasma anisotropic etch process to modify the top surface 118t to a specific shape. Without being bound by a particular theory, it is believed that by pulsing the bias voltage, the secondary etchant can help etching portions of the insulating material 118 located adjacent the well portion 116 at a faster rate than center portions of the insulating material 118. As a result, the modified top surface 118t′ of the exposed portions of the insulating material 118 has a profile different from that of the top surface 118t of the portions of the insulating material 118 covered by the sacrificial gate structures 130, as shown in FIGS. 8A and 8B. In some embodiments, the modified top surface 118t′ includes a modified center top surface 118tc′ and a modified edge top surface 118te′, as shown in FIG. 8B. In some embodiments, the modified center top surface 118tc′ has a curved profile, such as a convex profile. The edge top surface 118te′ and the center top surface 118tc′ form an angle A′, as shown in FIG. 8B. In some embodiments, the angle A′ is an acute angle, such as an angle ranging from about 20 degrees to about 70 degrees. Furthermore, in some embodiments, a highest point of the modified edge top surface 118te′ is located at a level in the Z direction substantially the same as a highest point of the modified center top surface 118tc′, as shown in FIG. 8B. By forming recesses 119 adjacent the well portions 116, the subsequently formed first and second spacers 138, 139 (FIG. 9) prevent formation of epitaxial materials from the well portions 116 or the first semiconductor material 150 (FIG. 11). As a result, the risk of merged source/drain regions is substantially reduced.

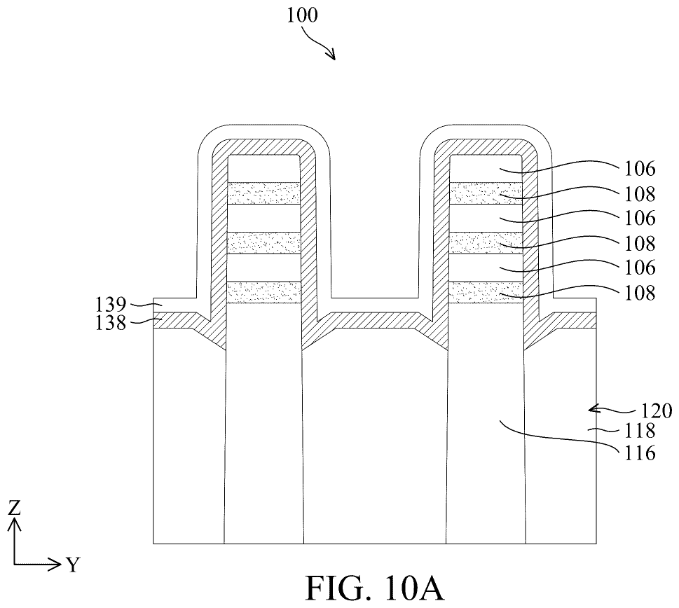

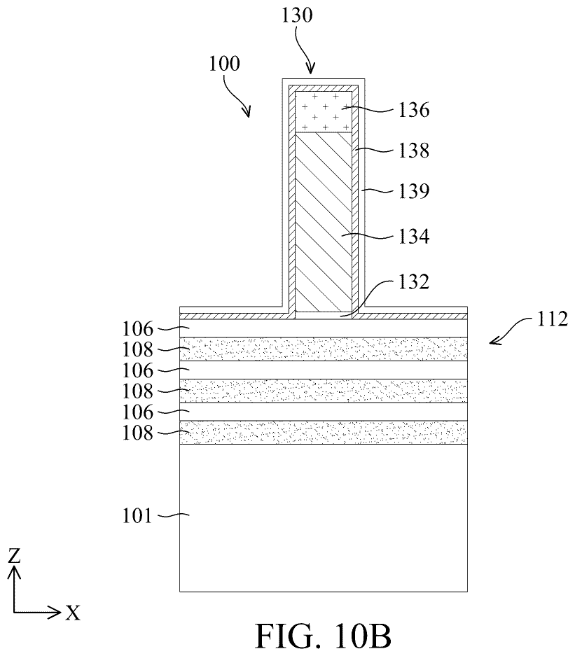

FIG. 9 is a perspective view of one of various stages of manufacturing the semiconductor device structure 100, in accordance with some embodiments. FIGS. 10A and 10B are cross-sectional side views of one of various stages of manufacturing the semiconductor device structure 100 taken along lines B-B, C-C of FIG. 5, respectively, in accordance with some embodiments. FIGS. 10A and 10B show the semiconductor device structure 100 at the same manufacturing stage as in FIG. 9. As shown in FIGS. 9, 10A and 10B, first and second spacers 138, 139 are deposited on the exposed surfaces of the semiconductor device structure 100. For example, the first spacer 138 is deposited on the fin structures 112, the isolation regions 120, and the sacrificial gate structure 130, and the second spacer 139 is deposited on the first spacer 138. The first spacer 138 may be made of a dielectric material such as silicon oxide, silicon nitride, silicon carbide, silicon oxynitride, SiCN, silicon oxycarbide, SiCON, and/or combinations thereof. The first spacer 138 may be formed by any suitable process. In some embodiments, the first spacer 138 is a conformal layer formed by a conformal process, such as an atomic layer deposition (ALD) process. The second spacer 139 may include any suitable dielectric material, such as SiOₓ, SiON, SiN, SiCON, or SiCO. The second spacer 139 may be formed by any suitable process. In some embodiments, the second gate spacer 139 is deposited by CVD, PECVD, ALD, or electron cyclotron resonance CVD (ECR-CVD).

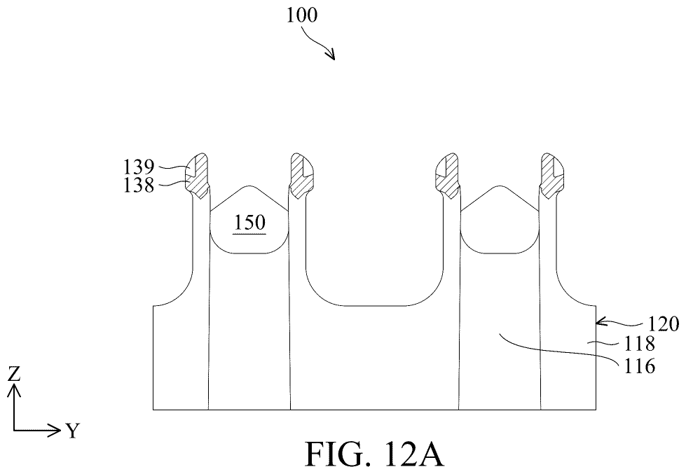

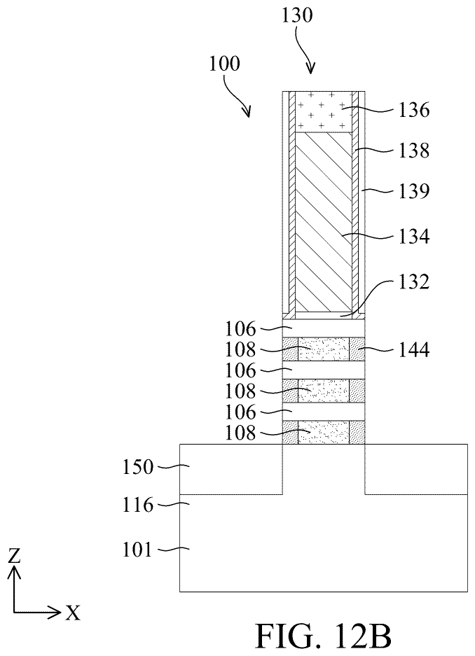

FIG. 11 is a perspective view of one of various stages of manufacturing the semiconductor device structure 100, in accordance with some embodiments. FIGS. 12A and 12B are cross-sectional side views of one of various stages of manufacturing the semiconductor device structure 100 taken along lines B-B, C-C of FIG. 5, respectively, in accordance with some embodiments. FIGS. 12A and 12B show the semiconductor device structure 100 at the same manufacturing stage as in FIG. 11. As shown in FIGS. 11, 12A, 12B, horizontal portions of the first and second spacers 138, 139 are removed and the portions of the fin structures 112 not covered by the sacrificial gate structure 130 and the first and second spacers 138, 139 are recessed. In some embodiments, the horizontal portions of the first and second spacers 138, 139 are removed by an anisotropic etch process. The anisotropic etch process may be a selective etch process that does not substantially affect the mask layer 136, the stack of semiconductor layers 104, and the isolation regions 120. The recess of the portions of the fin structures 112 can be done by an etch process. The etch process may be a dry etch, such as a RIE, NBE, or the like, or a wet etch, such as using tetramethyalammonium hydroxide (TMAH), ammonium hydroxide (NH₄OH), or any suitable etchant. The well portions 116 are exposed on opposite sides of the sacrificial gate structure 130, as shown in FIG. 12B. In some embodiments, the insulating material 118 is also recessed during the recessing of the fin structures 112, as shown in FIG. 12A. However, due to the first and second spacers 138, 139 formed in the recess 119 (FIG. 8B), the portion of the insulating material 118 located under the first and second spacers 138, 139 are protected. As a result, side surfaces of the well portion 116 and the subsequently formed first semiconductor material 150 are not exposed.

Next, as shown in FIGS. 11 and 12B, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

Next, as shown in FIGS. 11, 12A and 12B, the first semiconductor material 150 is formed on the exposed well portions 116. In some embodiments, the first semiconductor material 150 includes undoped silicon or undoped SiGe. The first semiconductor material 150 may be first formed on semiconductor surfaces, such as on the exposed well portions 116 and on the first semiconductor layers 106, by epitaxy. A subsequent etch process is performed to remove the portions of the first semiconductor material 150 formed on the first semiconductor layers 106. The first semiconductor material 150 formed on the exposed well portions 116 may form a concave top surface as the result of the etch process. In some embodiments, the first semiconductor material 150 has a thickness ranging from about 5 nm to about 50 nm along the Z direction.

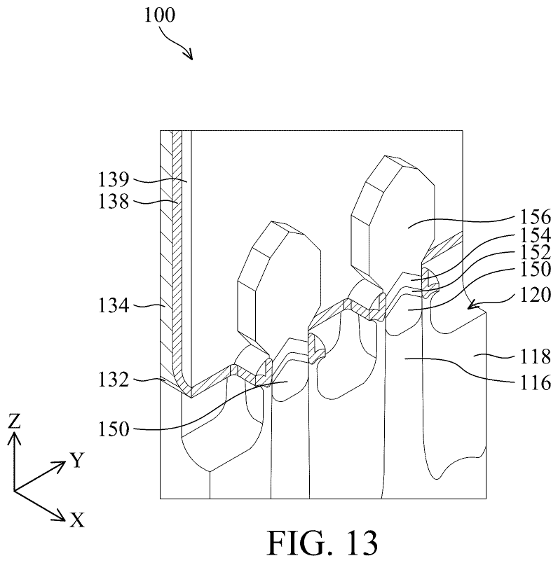

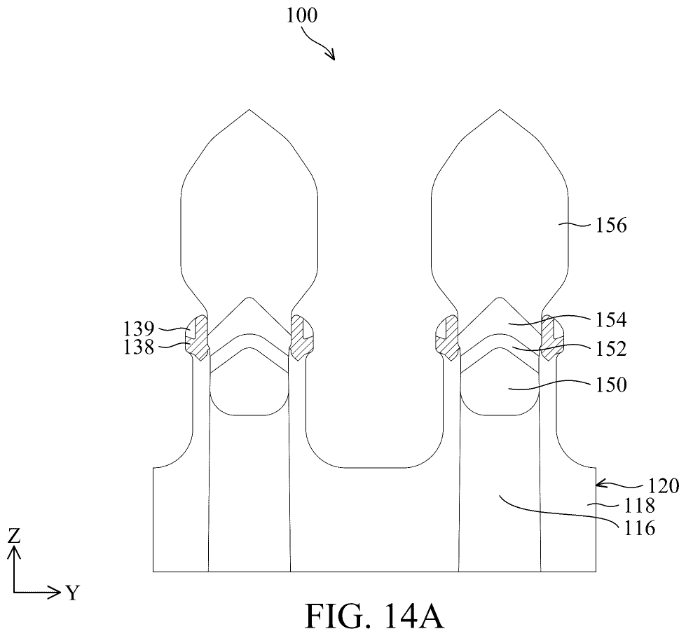

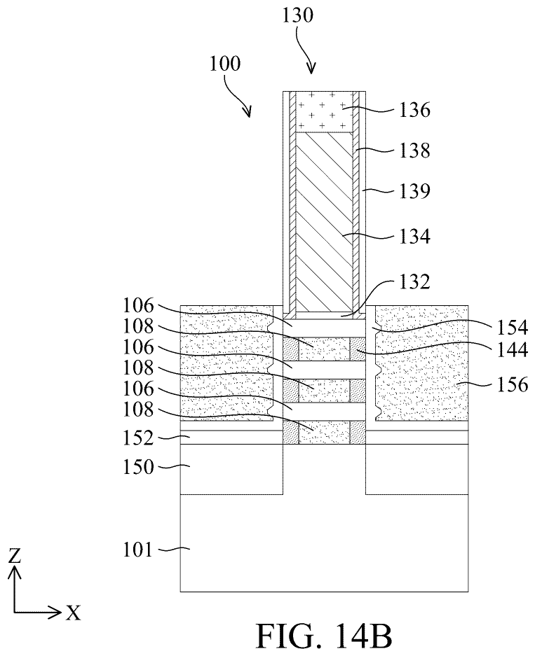

FIG. 13 is a perspective view of one of various stages of manufacturing the semiconductor device structure 100, in accordance with some embodiments. FIGS. 14A and 14B are cross-sectional side views of one of various stages of manufacturing the semiconductor device structure 100 taken along lines B-B, C-C of FIG. 5, respectively, in accordance with some embodiments. FIGS. 14A and 14B show the semiconductor device structure 100 at the same manufacturing stage as in FIG. 13. As shown in FIGS. 13, 14A, and 14B, a dielectric layer 152 is formed on the first semiconductor material 150. The dielectric layer 152 may be formed by first forming a dielectric layer on the exposed surfaces of the semiconductor device structure 100, followed by one or more etch processes to remove portions of the dielectric layer other than the dielectric layer 152. A mask layer (not shown), such as a bottom anti-reflective coating (BARC) layer, may be used to assist with the removal of the portions of the dielectric layer. The dielectric layer 152 may include any suitable dielectric material. In some embodiments, the dielectric layer 152 includes SiN. The dielectric layer 152 may be formed by any suitable process. In some embodiments, the dielectric layer 152 is formed by CVD. Next, a second semiconductor material 154 is formed from the first semiconductor layers 106. The second semiconductor material 154 may be made of one or more layers of Si, SiP, SiC, SiAs, SiSb, and SiCP for n-channel FETs or Si, SiGe, Ge for p-channel FETs. For p-channel FETs, p-type dopants, such as boron (B), may be included in the second semiconductor material 154. For n-channel FETs, n-type dopants, such as phosphorus (P) or arsenic (As), may be included in the second semiconductor material 154. As shown in FIG. 14B, in some embodiments, the second semiconductor material 154 is a continuous layer formed from the first semiconductor layers 106. In some embodiments, the second semiconductor material 154 is selectively formed on semiconductor materials, such as the first semiconductor layers 106, and is not formed on dielectric materials, such as the dielectric layer 152 and the dielectric spacers 144. In some embodiments, the second semiconductor material 154 includes facets, which may correspond to crystalline planes of the material used for the first semiconductor layers 106.

Next, as shown in FIGS. 13, 14A, and 14B, a third semiconductor material 156 is formed from the second semiconductor material 154. The third semiconductor material 156 may be formed by an epitaxial growth method using CVD, ALD or MBE. The third semiconductor material 156 may be made of one or more layers of Si, SiP, SiC and SiCP for n-type FETs or Si, SiGe, Ge for p-type FETs. For p-type FETs, p-type dopants, such as boron (B), may be included in the third semiconductor material 156. For n-type FETs, n-type dopants, such as phosphorus (P) or arsenic (As), may be included in the third semiconductor material 156. In some embodiments, the second semiconductor material 154 and the third semiconductor material 156 may include the same semiconductor materials but with different dopant concentrations. In some embodiments, the dielectric layer 152 is not present, and the third semiconductor material 156 is grown from the first semiconductor material 150 and the second semiconductor material 154.

In some embodiments, a cap layer (not shown) may be formed on the third semiconductor material 156. The cap layer may include a semiconductor material. In some embodiments, the cap layer includes the same material as the third semiconductor material. The cap layer may be epitaxially grown from the third semiconductor material 156.

The second semiconductor material 154 and the third semiconductor material 156 together may be the source/drain (S/D) region. In this disclosure, a source region and a drain region are interchangeably used, and the structures thereof are substantially the same. Furthermore, source/drain region(s) may refer to a source or a drain, individually or collectively dependent upon the context. In some embodiments, p-type S/D regions and n-type S/D regions may be formed separately using one or more mask layers. In some embodiments, the second semiconductor material 154 and the third semiconductor material 156 are crystalline semiconductor materials.

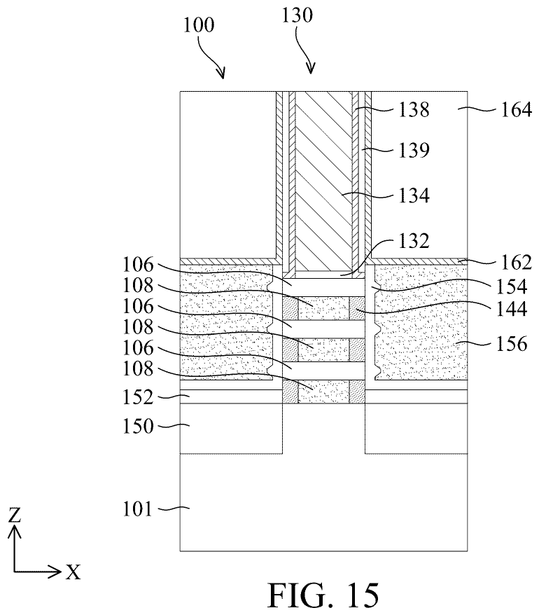

FIGS. 15-17 are cross-sectional side views of various stages of manufacturing the semiconductor device structure 100 taken along line C-C of FIG. 5, in accordance with some embodiments. As shown in FIG. 15, a contact etch stop layer (CESL) 162 is conformally formed on the exposed surfaces of the semiconductor device structure 100. The CESL 162 covers the second spacer 139, the isolation regions 120, and the third semiconductor material 156 (or the cap layer if present). The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. In some embodiments, the CESL 162 is a single layer, as shown in FIG. 15. In some embodiments, the CESL 162 includes two or more layers. Next, an interlayer dielectric (ILD) layer 164 is formed on the CESL 162. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIG. 15.

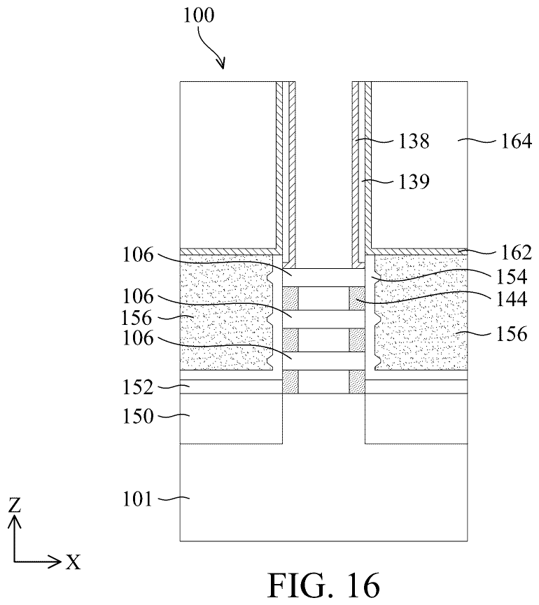

Next, as shown in FIG. 16, the sacrificial gate structure 130 and the second semiconductor layers 108 are removed. The removal of the sacrificial gate structure 130 and the semiconductor layers 108 forms an opening between the first gate spacers 138 and between the first semiconductor layers 106. The ILD layer 164 protects the second semiconductor material 156 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the first gate spacers 138, the ILD layer 164, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the first gate spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), or phosphoric acid (H₃PO₄).

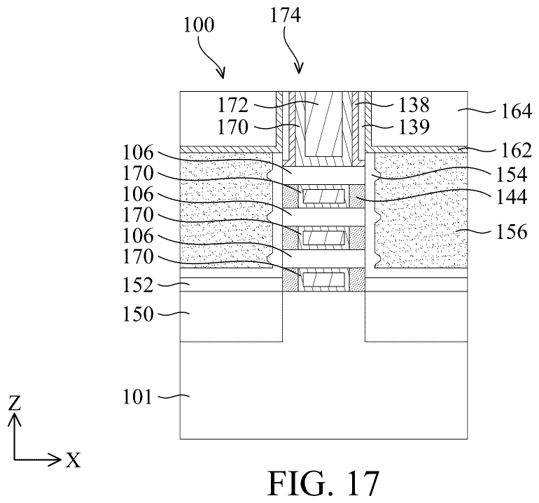

As shown in FIG. 17, after the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106, and one or more work function layers (not shown) are formed between the gate dielectric layer 170 and the gate electrode layer 172. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The work function layer may include polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, or other suitable materials. The gate electrode layer 172 may include one or more layers of conductive material, such as platinum (Pt), palladium (Pd), tantalum (Ta), ytterbium (Yb), aluminum (Al), silver (Ag), titanium (Ti), ruthenium (Ru), molybdenum (Mo), chromium (Cr), tungsten (W), copper (Cu), or similar material, and/or any combinations thereof. The gate electrode layer 172 may be formed by CVD, ALD, electro-plating, or other suitable deposition technique. The gate electrode layer 172 may also be deposited over the upper surface of the ILD layer 164. The gate dielectric layer 170 and the gate electrode layer 172 formed over the ILD layer 164 are then removed by using, for example, CMP, until the top surface of the ILD layer 164 is exposed.

After the formation of the gate structures 174, the top surface 118t of the insulating material 118 (isolation region 120) located under the gate structures 174 is not substantially changed, as shown in FIG. 6A.

It is understood that the semiconductor device structure 100 may undergo further processes, such as cut metal gate (CMG) process and/or continuous poly on diffusion edge (CPODE) process. The CMG process separates the gate electrode layer 172 into multiple segments that can be individually controlled. The CPODE process forms isolation between devices.

Embodiments of the present disclosure provide methods for forming a semiconductor device structure. In some embodiments, the method includes forming one or more sacrificial gate structures 130 and modify the top surface 118t of the insulation material 118 not covered by the sacrificial gate structures 130. The top surface 118t may be modified by a plasma etch process that etches edge portions of the insulating material 118 adjacent the well portions 116 at a faster rate than center portion of the insulating material 118. As a result, recesses are formed in the insulating material 118 adjacent the well portions 116. Some embodiments may achieve advantages. For example, the first and second spacers 138, 139 may be formed in recesses, and the first and second spacers 138, 139 protect portions of the insulating material 118 disposed thereunder during subsequent processes. As a result, side surfaces of the well portions 116 and/or the first semiconductor material 150 are not exposed during the subsequent process to form the second and third semiconductor materials, 154, 156. The risk of merged S/D regions is substantially reduced.

An embodiment is a method. The method includes forming a fin structure from a substrate, depositing an insulating material around the fin structure, recessing the insulating material, and forming a sacrificial gate structure over a first portion of the fin structure. A first portion of the insulating material is covered by the sacrificial gate structure, and a second portion of the insulating material is exposed. The method further includes modifying a top surface of the exposed second portion of the insulating material, and the modified top surface has a profile different from a top surface of the first portion of the insulating material. After the modifying of the top surface, the method further includes depositing a first spacer on the sacrificial gate structure a second portion of the fin structure and recessing the second portion of the fin structure.

Another embodiment is a method. The method includes forming a fin structure from a substrate, depositing an insulating material around the fin structure, recessing the insulating material, and forming a sacrificial gate structure over a first portion of the fin structure. A first portion of the insulating material is covered by the sacrificial gate structure, and a second portion of the insulating material is exposed. The method further includes performing a plasma etch process to etch the second portion of the insulating material, and a recess is formed in the second portion of the insulating material adjacent the fin structure. The method further includes depositing a first spacer on the sacrificial gate structure and a second portion of the fin structure, the first spacer is deposited in the recess in the second portion of the insulating material, and recessing the second portion of the fin structure.

A further embodiment is a method. The method includes forming a fin structure from a substrate, depositing an insulating material around the fin structure, recessing the insulating material, and forming a sacrificial gate structure over a first portion of the fin structure. A first portion of the insulating material is covered by the sacrificial gate structure, a second portion of the insulating material is exposed, the first portion of the insulating material includes a first top surface having a first center top surface and a first edge top surface, and a highest point of the first edge top surface is at a level substantially higher than a highest point of the first center top surface. The method further includes modifying a second top surface of the exposed second portion of the insulating material, the second top surface includes a second center top surface and a second edge top surface, and a highest point of the second edge top surface is at a level substantially the same as a highest point of the second center top surface. The method further includes depositing a first spacer on the sacrificial gate structure and a second portion of the fin structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a fin structure from a substrate;
depositing an insulating material around the fin structure;
recessing the insulating material;
forming a sacrificial gate structure over a first portion of the fin structure, wherein a first portion of the insulating material is covered by the sacrificial gate structure, and a second portion of the insulating material is exposed;
modifying a top surface of the exposed second portion of the insulating material, wherein the modified top surface has a profile different from a top surface of the first portion of the insulating material;
after the modifying of the top surface, depositing a first spacer on the sacrificial gate structure and a second portion of the fin structure; and
recessing the second portion of the fin structure.

2. The method of claim 1, further comprising depositing a second spacer on the first spacer.

3. The method of claim 2, further comprising removing horizontal portions of the first and second spacers prior to recessing the second portion of the fin structure.

4. The method of claim 1, wherein the second portion of the insulating material is recessed during the recessing of the second portion of the fin structure.

5. The method of claim 1, wherein a well portion is exposed after the recessing of the second portion of the fin structure.

6. The method of claim 5, further comprising:
depositing a first semiconductor material on the well portion;
depositing a second semiconductor material over the first semiconductor material; and
depositing a third semiconductor material on the second semiconductor material.

7. The method of claim 6, further comprising depositing a dielectric layer on the first semiconductor material, wherein the second semiconductor material is deposited on the dielectric layer.

8. A method, comprising:
forming a fin structure from a substrate;
depositing an insulating material around the fin structure;
recessing the insulating material;
forming a sacrificial gate structure over a first portion of the fin structure, wherein a first portion of the insulating material is covered by the sacrificial gate structure, and a second portion of the insulating material is exposed;
performing a plasma etch process to etch the second portion of the insulating material, wherein a recess is formed in the second portion of the insulating material adjacent the fin structure;
depositing a first spacer on the sacrificial gate structure and a second portion of the fin structure, wherein the first spacer is deposited in the recess in the second portion of the insulating material; and
recessing the second portion of the fin structure.

9. The method of claim 8, wherein the plasma etch process utilizes a main etchant and a secondary etchant.

10. The method of claim 9, wherein the main etchant comprises CF₄, and the secondary etchant comprises Ar.

11. The method of claim 10, wherein the plasma etch process comprises pulsing a bias voltage.

12. The method of claim 8, wherein the sacrificial gate structure is formed by a wet etch process.

13. The method of claim 8, wherein the first portion of the insulating material includes a first top surface having a first center top surface and a first edge top surface.

14. The method of claim 13, wherein a first angle formed between the first center top surface and the first edge top surface is an obtuse angle.

15. The method of claim 14, wherein the second portion of the insulating material includes a second top surface having a second center top surface and a second edge top surface.

16. The method of claim 15, wherein a second angle formed between the second center top surface and the second edge top surface is an acute angle.

17. A method, comprising:
forming a fin structure from a substrate;
depositing an insulating material around the fin structure;
recessing the insulating material;
forming a sacrificial gate structure over a first portion of the fin structure, wherein a first portion of the insulating material is covered by the sacrificial gate structure, a second portion of the insulating material is exposed, and the first portion of the insulating material includes a first top surface having a first center top surface and a first edge top surface, wherein a highest point of the first edge top surface is at a level substantially higher than a highest point of the first center top surface;
modifying a second top surface of the exposed second portion of the insulating material, wherein the second top surface includes a second center top surface and a second edge top surface, and a highest point of the second edge top surface is at a level substantially the same as a highest point of the second center top surface; and
depositing a first spacer on the sacrificial gate structure and a second portion of the fin structure.

18. The method of claim 17, further comprising depositing a second spacer on the first spacer.

19. The method of claim 18, further comprising removing horizontal portions of the first and second spacers and recessing a second portion of the fin structure.

20. The method of claim 17. wherein the second top surface is modified by a plasma etch process.
